(19) United States
(12) Patent Application Publication
(10) Pub. No.: US 2025/0096070 A1
(43) Pub. Date: Mar. 20, 2025

(54) SEMICONDUCTOR MODULE

(71) Applicant: Murata Manufacturing Co., Ltd., Kyoto-fu (JP)

(72) Inventor: Mari SAJI, Nagaokakyo-shi (JP)

(73) Assignee: Murata Manufacturing Co., Ltd., Kyoto-fu (JP)

(21) Appl. No.: 18/964,045

(22) Filed: Nov. 29, 2024

Related U.S. Application Data
(63) Continuation of application No. PCT/CN2023/024811, filed on Jul. 4, 2023.

(30) Foreign Application Priority Data
Jul. 14, 2022 (JP) 2022-113101

(51) Int. Cl. H01L 23/373; H01L 23/00; H01L 23/14; H01L 23/29; H01L 23/367

(52) U.S. Cl. CPC H01L 23/3737; H01L 23/145; H01L 23/295; H01L 23/367; H01L 24/16; H01L 2224/16227; H01L 2224/16238; H01L 2924/13091

(57) ABSTRACT

A semiconductor device is flip-chip mounted on a mounting substrate. A mold resin seals the semiconductor device. An insulating heat transfer member having a thermal conductivity higher than a thermal conductivity of the mold resin is on a surface of the semiconductor device facing the mounting substrate. The semiconductor device includes a device layer including a transistor, a plurality of bumps that are on a surface of the device layer facing the mounting substrate and are connected to the mounting substrate, and an insulating layer that is on a surface of the device layer opposite to the surface facing the mounting substrate. When the mounting substrate is viewed in plan view, the transistor has a non-overlapping portion that does not overlap with any of the bumps. The heat transfer member is continuous from a region overlapping with the non-overlapping portion to at least one of the bumps.

### CROSS-REFERENCE TO RELATED APPLICATIONS

This application claims benefit of priority to International Patent Application No. PCT/JP2023/024811, filed Jul. 4, 2023, and to Japanese Patent Application No. 2022-113101, filed Jul. 14, 2022, the entire contents of each are incorporated herein by reference.

### BACKGROUND

### Technical Field

The present disclosure relates to a semiconductor module.

### Background Art

In a semiconductor device in which a high-frequency circuit is formed on an SOI substrate, in which an insulating layer and a semiconductor layer are laminated on a support substrate made of silicon, harmonic distortion may occur due to parasitic capacitance between the semiconductor layer and the support substrate. A semiconductor device in which parasitic capacitance is reduced by removing a support substrate made of silicon after mounting a semiconductor device fabricated with an SOI substrate on a mounting substrate is disclosed in U.S. Patent Application Publication No. 2019/0326159. A resin is disposed in the space after the support substrate is removed.

### SUMMARY

The heat generated by the transistors formed in a semiconductor layer is considered to be conducted to a mounting substrate mainly through the nearest bump. However, according to the consideration by the inventor of the present application, it was found that in the semiconductor device with the structure disclosed in U.S. Patent Application Publication No. 2019/0326159, the temperature of the transistor tends to rise more easily than in the configuration where the support substrate made of Si of the SOI substrate is left in place.

Accordingly, the present disclosure provides a semiconductor module capable of suppressing an increase in parasitic capacitance generated in a semiconductor layer and suppressing a temperature rise of a transistor formed in the semiconductor layer.

According to one aspect of the present disclosure, a semiconductor module includes a mounting substrate, a semiconductor device that is flip-chip mounted on the mounting substrate, a mold resin that seals the semiconductor device, and an insulating heat transfer member that is disposed on a surface of the semiconductor device facing the mounting substrate and has a higher thermal conductivity than a thermal conductivity of the mold resin. The semiconductor device includes a device layer in which a transistor is formed, a plurality of bumps that are disposed on a surface of the device layer facing the mounting substrate and are connected to the mounting substrate, and an insulating layer that is disposed on a surface of the device layer opposite to the surface facing the mounting substrate. When the mounting substrate is viewed in plan view, the transistor has a non-overlapping portion not overlapping with any of the plurality of bumps, and the heat transfer member is continuously disposed from a region overlapping with the non-overlapping portion to at least one of the plurality of bumps.

Heat generated in a non-overlapping portion of a transistor is conducted through a heat transfer member to a bump at which the heat transfer member is continuous. Therefore, it is possible to suppress the temperature rise in the non-overlapping portion of the transistor.

### BRIEF DESCRIPTION OF THE DRAWINGS

FIG. 1 is a schematic view showing a planar positional relationship between some constituent elements of a semiconductor device mounted on a semiconductor module according to a first embodiment;

FIG. 2 is a cross-sectional view of a portion of the semiconductor module according to the first embodiment;

FIGS. 3A to 3D are schematic cross-sectional views of the semiconductor device mounted on the semiconductor module according to the first embodiment in the middle of manufacturing;

FIG. 4A shows a positional relationship in plan view between a transistor and a plurality of bumps in the semiconductor device, and FIG. 4B is a schematic perspective view of a state where the semiconductor device is mounted on a mounting substrate;

FIG. 5A is a schematic cross-sectional view of the semiconductor module according to the first embodiment, and FIG. 5B is a schematic cross-sectional view of a semiconductor device and a mounting substrate according to a comparative example;

FIGS. 6A to 6D are schematic cross-sectional views of a semiconductor device mounted in a semiconductor module according to a modification of the first embodiment in the middle of manufacturing;

FIGS. 7A and 7B are diagrams showing a planar positional relationship between a plurality of constituent elements of a semiconductor device mounted on a semiconductor module according to another modification of the first embodiment;

FIG. 8 is a schematic cross-sectional view of a semiconductor module according to a second embodiment;

FIGS. 9A and 9B are cross-sectional views of the semiconductor module according to the second embodiment in the middle of manufacturing; and

FIG. 10 is a block diagram of a high-frequency module according to a third embodiment.

### DETAILED DESCRIPTION

### First Embodiment

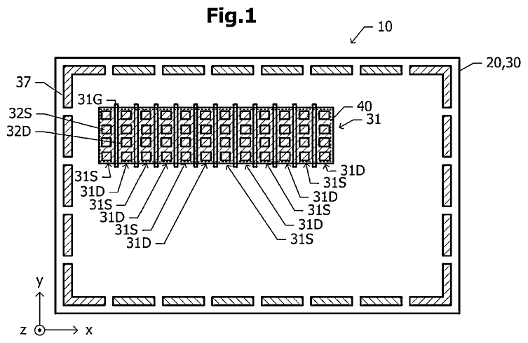

A semiconductor module according to a first embodiment will be described with reference to the diagrams from FIGS. 1 to 5B.

FIG. 1 is a schematic view showing a planar positional relationship between some constituent elements of a semiconductor device 10 mounted on a semiconductor module according to the first embodiment. An insulating layer 20 and a device layer 30 are disposed to substantially overlap with each other in plan view. A transistor 31 is disposed in an inner region of the device layer 30.

The transistor 31 is, for example, a multi-finger type MOS-FET, and includes a plurality of source regions 31S, a plurality of drain regions 31D, and a plurality of gate electrodes 31G. The plurality of source regions 31S and the plurality of drain regions 31D are arranged alternately in one direction in the active region. A plane parallel to the surface of the device layer 30 is defined as an xy plane, and an xyz orthogonal coordinate system is defined in which a direction in which the plurality of source regions 31S and the plurality of drain regions 31D are arranged is defined as an x direction. The gate electrodes 31G are disposed between the source regions 31S and the drain regions 31D adjacent to each other.

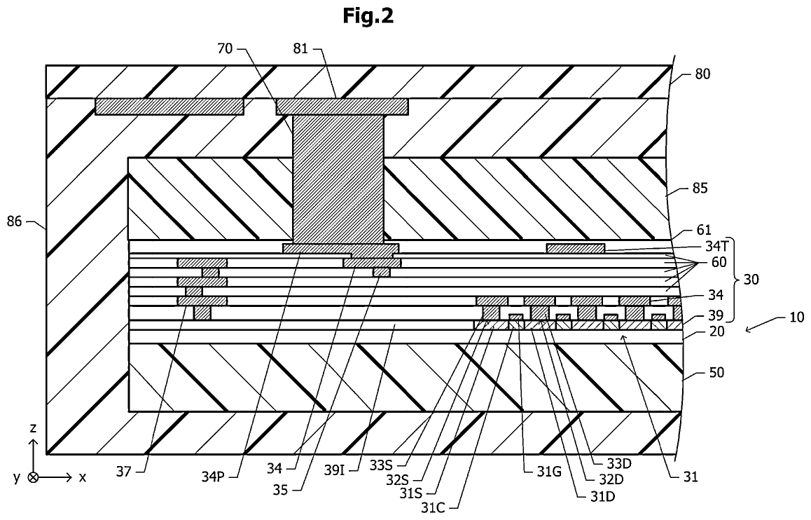

In plan view, a plurality of source contact regions 32S arranged in the y direction are defined inside each of the plurality of source regions 31S. Similarly, a plurality of drain contact regions 32D arranged in the y direction are defined inside each of the plurality of drain regions 31D. Here, the source contact region 32S means a region where the source region 31S and a source contact electrode (described later with reference to FIG. 2) are in ohmic contact with each other, and the drain contact region 32D means a region where the drain region 31D and a drain contact electrode (described later with reference to FIG. 2) are in ohmic contact with each other. The term “in plan view” means that the device layer 30 in which the transistor 31 is disposed is viewed in plan view from the lamination direction of the insulating layer 20 and the device layer 30.

A high-frequency circuit is composed of the transistor 31 and a wiring line (not shown in FIG. 1). Examples of the high-frequency circuit include a low-noise amplifier that amplifies a high-frequency signal, a switch that selects one from a plurality of duplexers, filters, or the like provided for each frequency band, and the like. The switch is composed of, for example, a CMOS-FET.

In plan view, a rectangle having the smallest area including all of the plurality of source contact regions 32S and the plurality of drain contact regions 32D of the transistor 31 is referred to as a minimum enclosing rectangle 40. In FIG. 1, the broken line indicates an outer peripheral line of the minimum enclosing rectangle 40, and hatching is added to the inside of the minimum enclosing rectangle 40. The region inside the minimum enclosing rectangle 40 can be considered as a region where the transistor 31 is substantially disposed.

A metal layer 37 is disposed slightly inside the outer peripheral line of the device layer 30 to surround the internal region of the device layer 30 in plan view. The metal layer 37 is also called a guard ring. The metal layer 37 is isolated into a plurality of portions in the circumferential direction. The metal layer 37 may be configured to be continuous in the circumferential direction such that the metal layer 37 has a closed annular shape in plan view.

FIG. 2 is a cross-sectional view of a portion of the semiconductor module according to the first embodiment. The semiconductor module according to the first embodiment includes a mounting substrate 80, the semiconductor device 10 mounted on the mounting substrate 80, a heat transfer member 85, and a mold resin 86.

The semiconductor device 10 includes a device layer 30, an insulating layer 20, a support substrate 50 made of an insulating resin, and a plurality of bumps 70. In FIG. 2, one of the plurality of bumps 70 is shown. A direction from the semiconductor device 10 to the mounting substrate 80 is defined as an upward direction.

The device layer 30 is disposed on a surface of the insulating layer 20 facing upward, and the support substrate 50 is disposed on a surface of the insulating layer 20 facing downward. The insulating layer 20 may be composed of a single layer or a plurality of layers. For example, in a case where the insulating layer 20 is composed of a single layer, silicon oxide is used as a material of the insulating layer 20. In a case where the insulating layer 20 is composed of a plurality of layers, for example, silicon oxide or silicon nitride is used as a material of each layer. As the resin material of the support substrate 50, in order to prevent the high-frequency characteristics of the semiconductor device 10 from being adversely affected, it is preferable to use a material having a low conductivity and a low dielectric loss tangent. For example, polyimide can be used as a material of the support substrate 50. The thermal conductivity of the polyimide is about 0.25 W/m. K.

The device layer 30 includes an element formation layer 39 made of a semiconductor and in contact with the insulating layer 20, and a multilayer wiring layer disposed on the element formation layer 39. The element formation layer 39 is composed of an active region made of silicon and an insulating element isolation region 39I surrounding the active region. The plurality of source regions 31S, the plurality of drain regions 31D, and a plurality of channel regions 31C of the transistor 31 are disposed in the active region of the element formation layer 39.

The plurality of source regions 31S and the plurality of drain regions 31D are disposed in a row in the x direction at intervals. The channel region 31C is defined between the source region 31S and the drain region 31D adjacent to each other. The gate electrode 31G is disposed on the channel region 31C with a gate insulating film (not shown) interposed therebetween.

The multilayer wiring layer on the element formation layer 39 includes a plurality of insulating layers 60. For the plurality of insulating layers 60, for example, a low dielectric constant material (Low-k material) is used. SiN or an organic insulating material is used for the uppermost insulating layer 60.

The source contact electrodes 33S and the drain contact electrodes 33D are filled in the via holes provided in the lowermost insulating layer 60 of the multilayer wiring layer. The source contact electrode 33S is in ohmic contact with the source region 31S in the source contact region 32S, and the drain contact electrode 33D is in ohmic contact with the drain region 31D in the drain contact region 32D. The source contact electrode 33S and the drain contact electrode 33D are formed of, for example, W. A close-contact layer such as TiN may be disposed as necessary for the purpose of improving close contact. A film made of metal silicide such as CoSi and NiSi may be formed on each of the surfaces of the source region 31S and the drain region 31D to form a structure for reducing the resistance of the contact portion.

A plurality of wiring lines 34 or a plurality of vias 35 are disposed in each of the plurality of insulating layers 60 which are the second or subsequent layers. For the formation of the wiring line 34 or the via 35, a damascene method, a dual damascene method, or a subtractive method is used. A plurality of wiring lines 34T and a plurality of pads 34P are disposed in the uppermost wiring layer of the device layer 30. As an example, the wiring lines 34 and 34T and the pad 34P are formed of Cu or Al, and the via is formed of Cu or W. As necessary, a close-contact layer such as TiN may be disposed for the purpose of preventing diffusion or improving close contact. The metal layer 37 called a guard ring is disposed in a peripheral edge portion of the multilayer wiring layer.

A protective film 61 made of an organic insulating material is disposed on the device layer 30 to cover the uppermost layer wiring line 34T and the pad 34P. Examples of the organic insulating material used for the protective film 61 include polyimide and benzocyclobutene (BCB). A plurality of openings exposing the upper surface of each of the plurality of pads 34P are provided in the protective film 61, and the bump 70 is disposed on the pad 34P in the opening. The bump 70 is composed of, for example, an under bump metal layer, a Cu pillar, and a solder layer. As the bump 70, a bump having another structure may be used.

The bump 70 is connected to a land 81 of the mounting substrate 80, whereby the semiconductor device 10 is flip-chip mounted on the mounting substrate 80. The heat transfer member 85 is disposed on a surface of the device layer 30 facing the mounting substrate 80 with the protective film 61 interposed therebetween. The heat transfer member 85 is not disposed in a region where the bumps 70 are disposed. The heat transfer member 85 is thermally coupled to the device layer 30 with the protective film 61 interposed therebetween. Further, the heat transfer member 85 is in contact with the side surface of the bump 70 and is thermally coupled to the bump 70.

The semiconductor device 10 and the heat transfer member 85 are sealed with the mold resin 86. Specifically, the mold resin 86 is in contact with a surface of the semiconductor device 10 opposite to the surface facing the mounting substrate 80 and a side surface of the semiconductor device 10, and is filled in a space between the heat transfer member 85 and the mounting substrate 80. For the mold resin 86, for example, a filler-containing epoxy resin is used. As the filler, for example, silica is used, and a filling rate of the filler is, for example, 70 wt %.

The heat transfer member 85 is formed of an insulating material, and the thermal conductivity of the heat transfer member 85 is higher than the thermal conductivity of the mold resin 86. Further, the thermal conductivity of the heat transfer member 85 is higher than the thermal conductivity of the support substrate 50. For the heat transfer member 85, for example, a filler-containing epoxy resin is used. As the filler, for example, silica is used, and a filling rate of the filler is, for example, 80 wt %. Other resins, for example, a silicone-based resin may be used instead of the epoxy resin. As the filler, alumina or the like may be used instead of silica, or alumina may be used together with silica.

The material and the filling rate of the filler mixed with the resin material of the heat transfer member 85 and the mold resin 86 are adjusted such that the thermal conductivity of the heat transfer member 85 is higher than the thermal conductivity of the mold resin 86. For example, the weight filling rate of the filler of the heat transfer member 85 is higher than the weight filling rate of the filler of the mold resin 86.

The thickness of the device layer 30 is, for example, 10 μm, and the thickness of the bump 70 is, for example, 160 μm. The thickness of the heat transfer member 85 is, for example, 1/10 or more of the thickness of the bump 70. That is, the thickness of the heat transfer member 85 is 100 times or more the thickness of the device layer 30. In addition, the thermal conductivity of the heat transfer member 85 is higher than the thermal conductivities of the support substrate 50 and the mold resin 86. Therefore, the heat generated in the transistor 31 is mainly conducted in the multilayer wiring layer of the device layer 30 in the thickness direction and reaches the heat transfer member 85, and then the heat is conducted in the in-plane direction of the heat transfer member 85 and reaches the bump 70.

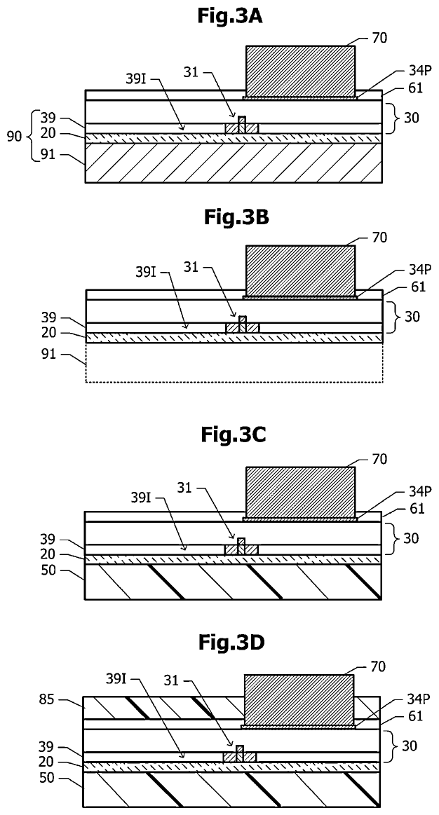

Next, a manufacturing method of the semiconductor device 10 mounted in the semiconductor module according to the first embodiment will be described with reference to the drawings of FIGS. 3A to 3D. The views from FIG. 3A to FIG. 3D are schematic cross-sectional views of the semiconductor device 10 mounted in the semiconductor module according to the first embodiment in the middle of manufacturing.

As shown in FIG. 3A, an SOI substrate 90 including a temporary support substrate 91 made of silicon, the insulating layer 20 made of silicon oxide, and the element formation layer 39 made of silicon is prepared. The element isolation region 39I is formed in a part of the element formation layer 39, and the transistor 31 is formed in the active region. In FIG. 3A, the source region 31S, the drain region 31D, and the gate electrode 31G are schematically shown one by one. Further, a multilayer wiring layer of the element formation layer 39 is formed. The multilayer wiring layer includes an uppermost layer pad 34P. The device layer 30 is composed of the element formation layer 39 and the multilayer wiring layer. The protective film 61 made of an organic insulating material is formed on the device layer 30, and a bump 70 is further formed. These structures can be formed by using a general semiconductor wafer process.

As shown in FIG. 3B, the temporary support substrate 91 is etched and removed. Before etching and removing of the temporary support substrate 91, a protective tape (not shown) or the like is affixed to the surface opposite to the temporary support substrate 91. By removing the temporary support substrate 91, one surface of the insulating layer 20 is exposed.

As shown in FIG. 3C, the support substrate 50 made of polyimide or the like is attached to the exposed surface of the insulating layer 20. As shown in FIG. 3D, the heat transfer member 85 is formed on the exposed surface of the protective film 61. For example, a coating method can be used to form the heat transfer member 85. After forming the heat transfer member 85, the laminated structure from the support substrate 50 to the heat transfer member 85 is cut with a dicing machine to form individual pieces.

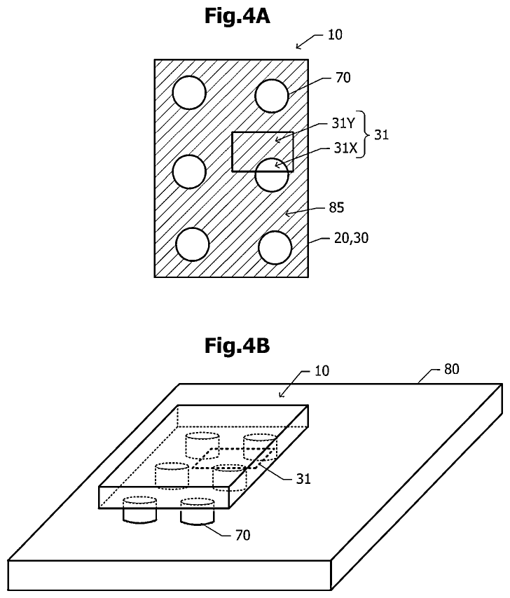

Next, a positional relationship between the transistor 31 of the semiconductor device 10 and the plurality of bumps 70 in plan view will be described with reference to FIGS. 4A and 4B. FIG. 4A is a diagram showing a positional relationship between the transistor 31 of the semiconductor device 10 and the plurality of bumps 70 in plan view, and FIG. 4B is a schematic perspective view of a state where the semiconductor device 10 is mounted on the mounting substrate 80. In addition to the transistor 31, a plurality of transistors are disposed in the element formation layer 39 (FIG. 2) of the semiconductor device 10. The heat transfer member 85 is disposed in the entire region of the insulating layer 20 and the device layer 30 in which the bumps 70 are not disposed in plan view. In FIG. 4A, a region where the heat transfer member 85 is disposed is hatched.

The plurality of bumps 70 of the semiconductor device 10 are connected to the mounting substrate 80. In plan view, a portion of the transistor 31 overlaps with one bump 70, and the other portion does not overlap with any bump 70. “A portion of the transistor 31 overlaps with the other portion in plan view” means that the minimum enclosing rectangle 40 shown in FIG. 1 overlaps with the other portion.

A portion of the transistor 31 overlapping with the bump 70 is referred to as an overlapping portion 31X, and a portion not overlapping with the bump 70 is referred to as a non-overlapping portion 31Y. In plan view, an area of the non-overlapping portion 31Y is larger than an area of the overlapping portion 31X. When the semiconductor device 10 is operated, the transistor 31 becomes a main heat source.

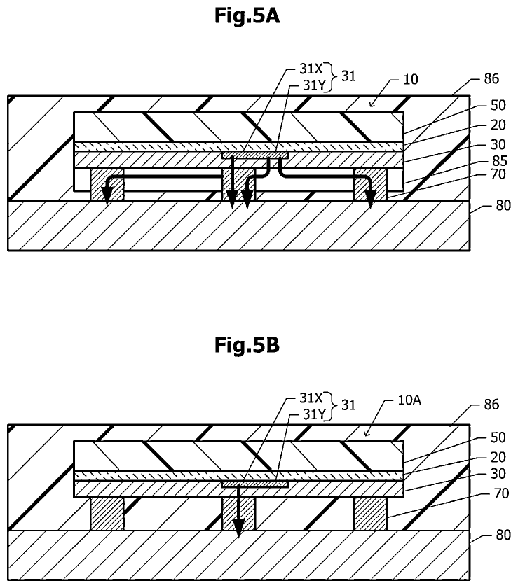

Next, an advantageous effect of the first embodiment will be described with reference to FIGS. 5A and 5B.

FIG. 5B is a schematic cross-sectional view of a semiconductor device 10A and the mounting substrate 80 according to a comparative example. The semiconductor device 10 is mounted on the mounting substrate 80 by connecting the plurality of bumps 70 to the mounting substrate 80. In the semiconductor device 10A according to the comparative example, the heat transfer member 85 (FIG. 5A) is not disposed. In the configuration in which the support substrate made of Si of the SOI substrate is left in place, the problem due to the temperature rise of the transistor 31 is not significant. Since the heat generated by transistor 31 is conducted to mounting substrate 80 through the nearest 70 bump, it is considered that sufficient heat dissipation efficiency is achieved.

However, as shown in FIG. 5B, experiments conducted by the inventor revealed that when the support substrate made of Si is removed and the support substrate 50 made of resin is disposed instead, the temperature of transistor 31 rises significantly. The phenomenon of heat generated in the transistor 31 being conducted to the mounting substrate 80 through the nearest 70 bump is common to both the configuration in FIG. 5B and the configuration in which the support substrate made of Si is left in place. It is considered that the reason why a sufficient heat dissipation efficiency can be obtained in a configuration in which the support substrate made of Si is left in place is that the support substrate consisting of Si also functions as a heat transfer path. That is, the heat generated in the non-overlapping portion 31Y of the transistor 31 is conducted to the bump 70 through the support substrate.

When the support substrate made of Si is replaced with the support substrate 50 made of a resin having a low thermal conductivity, the support substrate 50 does not substantially function as a heat transfer path. Therefore, the thermal resistance from the non-overlapping portion 31Y of the transistor 31 to the nearest bump 70 is increased. As a result, it is considered that the temperature rise of the non-overlapping portion 31Y of the transistor 31 is remarkable.

FIG. 5A is a schematic cross-sectional view of the semiconductor module according to the first embodiment. The arrow shown in FIG. 5A indicates a main heat transfer path through which the heat generated in the transistor 31 is conducted to the mounting substrate 80.

The heat generated in the overlapping portion 31X of the transistor 31 is mainly conducted to the mounting substrate 80 through the bump 70 which overlaps with the overlapping portion 31X of the transistor 31 in plan view. The heat generated in the non-overlapping portion 31Y of the transistor 31 is mainly conducted to the bumps 70 overlapping with the transistor 31 through the heat transfer member 85. Further, the heat generated in the transistor 31 is diffused in the in-plane direction through the heat transfer member 85 and is also conducted to the bump 70 that does not overlap with the transistor 31.

In the structure in which the support substrate made of Si is left in place, the role of the support substrate made of Si as a heat transfer path is played by the heat transfer member 85 in the semiconductor module according to the first embodiment. Therefore, the heat generated in the non-overlapping portion 31Y of the transistor 31 is diffused in the in-plane direction in the heat transfer member 85 and is conducted to the bump 70. As a result, the heat dissipation efficiency from the non-overlapping portion 31Y of the transistor 31 is improved, and the temperature rise of the non-overlapping portion 31Y can be suppressed.

Further, in the first embodiment, the heat transfer member 85 is also in contact with the bump 70 that does not overlap with the transistor 31 in plan view. Therefore, the bump 70 that does not overlap with the transistor 31 also functions as a heat transfer path from the transistor 31 to the mounting substrate 80. Since the plurality of bumps 70 function as the heat transfer path, the heat dissipation efficiency from the transistor 31 is improved, and the temperature rise of the transistor 31 can be suppressed.

In the configuration in which the heat transfer member 85 is not disposed, the thermal resistance from the non-overlapping portion 31Y of the transistor 31 to the bump 70 is higher than the thermal resistance from the overlapping portion 31X to the bump 70. The heat transfer member 85 has a function of reducing a thermal resistance from the non-overlapping portion 31Y of the transistor 31 to the bump 70. Therefore, in a case where the area of the non-overlapping portion 31Y of the transistor 31 is larger than the area of the overlapping portion 31X, the effect of disposing the heat transfer member 85 is further enhanced.

Further, since the heat transfer member 85 is formed of an insulating material, the parasitic capacitance generated in the device layer 30 is not increased. Therefore, the deterioration of the high-frequency characteristics of the semiconductor device 10 is suppressed.

Next, a semiconductor module according to a modification of the first embodiment will be described. In the first embodiment, although the resin containing a filler is used as the heat transfer member 85 (FIG. 5A), in the present modification, an inorganic insulating material having a thermal conductivity higher than the thermal conductivity of the mold resin 86 is used. Examples of the inorganic insulating material used for the heat transfer member 85 include diamond-like carbon (DLC).

In a case where the heat transfer member 85 is formed of DLC, for example, when XPS analysis is performed on a surface (surface in contact with the support substrate 50) downward-facing the insulating layer 20, a peak of sp3 is detected in the spectrum analysis of carbon. In addition, the material of the heat transfer member 85 is not limited to DLC. For example, the heat transfer member 85 may include a material such as alumina (including sapphire), aluminum nitride, or boron nitride. The thermal conductivity of these materials is as shown in the following table, for example.

TABLE 1

| | Thermal |
|---|---|
| | Conductivity |
| Material | [W/m · K] |
| DLC | 1000 |
| Alumina (including sapphire) | 42 |
| Aluminum nitride | 320 |
| Boron nitride | 410 |

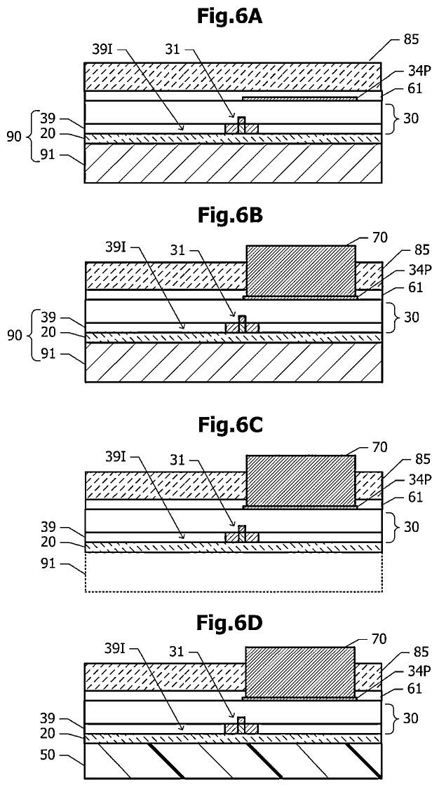

Next, a method of manufacturing the semiconductor device 10 mounted in the semiconductor module according to the present modification will be described with reference to the views of FIG. 6A to FIG. 6D. The views from FIG. 6A to FIG. 6D are schematic cross-sectional views of the semiconductor device 10 mounted in the semiconductor module according to the present modification in the middle of manufacturing.

In the first embodiment, the bump 70 (FIG. 3A) is formed before forming the heat transfer member 85 (FIG. 3D). On the other hand, in the present modification, as shown in FIG. 6A, the heat transfer member 85 made of DLC is formed on the protective film 61 before the bump 70 is formed after the protective film 61 is formed. In the formation of the heat transfer member 85 made of DLC, for example, plasma chemical vapor deposition (P-CVD) using a hydrocarbon-based gas, sputtering using a solid carbon target, or the like can be used.

As shown in FIG. 6B, an opening that penetrates the heat transfer member 85 and the protective film 61 to reach the pad 34P is formed in the region where the bump 70 is to be formed, and the bump 70 is formed on the pad 34P in this opening.

As shown in FIG. 6C, by etching and removing the temporary support substrate 91, the lower surface of the insulating layer 20 is exposed. As shown in FIG. 6D, the support substrate 50 is attached to the lower surface of the exposed insulating layer 20.

As in the present modification, as the heat transfer member 85, an inorganic insulating material having a thermal conductivity higher than the thermal conductivity of the mold resin 86 (FIG. 5A) may be used. Even in the present modification, the same excellent effects as those of the first embodiment can be obtained, that is, the temperature rise of the transistor 31 is suppressed, and the parasitic capacitance generated in the device layer 30 is not increased.

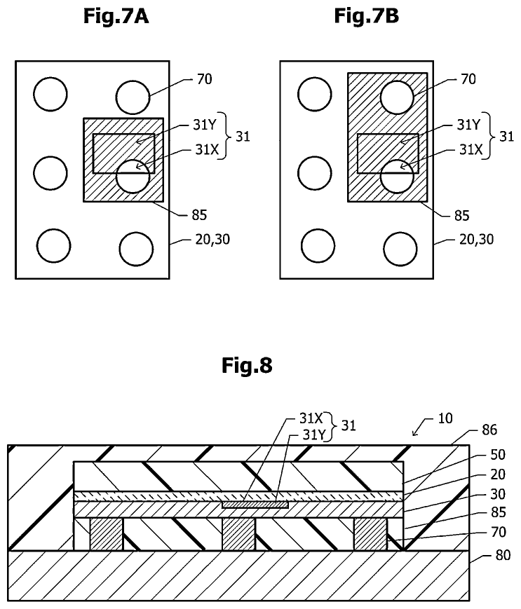

Next, a semiconductor module according to another modification of the first embodiment will be described with reference to FIGS. 7A and 7B. FIGS. 7A and 7B are diagrams showing a planar positional relationship between a plurality of constituent elements of the semiconductor device 10 mounted in the semiconductor module according to the present modification. In FIGS. 7A and 7B, a region where the heat transfer member 85 is disposed is hatched. In the first embodiment (FIG. 4A), the heat transfer member 85 is disposed in the entire region of the device layer 30 except for the region where the bump 70 is disposed. On the other hand, in the modifications shown in FIGS. 7A and 7B, the heat transfer member 85 is disposed only in a part of the region of the device layer 30.

In the modification shown in FIG. 7A, the heat transfer member 85 includes the non-overlapping portion 31Y of the transistor 31 in plan view, and is in contact with one bump 70 that overlaps with the transistor 31. The heat generated in the non-overlapping portion 31Y of the transistor 31 is conducted to the bump 70 overlapping with the transistor 31 through the heat transfer member 85. Therefore, the heat dissipation efficiency of the heat generated in the non-overlapping portion 31Y can be improved.

In the modification shown in FIG. 7B, the heat transfer member 85 includes the non-overlapping portion 31Y of the transistor 31 in plan view and is in contact with the bump 70 that overlaps with the transistor 31 and the one bump 70 that does not overlap with the transistor 31. The heat generated in the overlapping portion 31X and the non-overlapping portion 31Y of the transistor 31 is conducted to the two bumps 70 through the heat transfer member 85. Therefore, the heat dissipation efficiency from the transistor 31 can be further improved as compared with the modification shown in FIG. 7A.

As in the modifications shown in FIGS. 7A and 7B, the heat transfer member 85 does not necessarily need to be disposed over the entire region of the device layer 30. In particular, in order to improve the heat dissipation efficiency from the non-overlapping portion 31Y of the transistor 31, the heat transfer member 85 may be continuously disposed from a region overlapping with the non-overlapping portion 31Y to a portion in contact with at least one of the plurality of bumps 70.

In FIGS. 7A and 7B, the heat transfer member 85 includes one or two bumps 70 in plan view, but the heat transfer member 85 may be configured to overlap with or in contact with a portion of each of one or the plurality of bumps 70. In addition, in FIGS. 7A and 7B, the heat transfer member 85 includes the non-overlapping portion 31Y in plan view, but the heat transfer member 85 may be configured to overlap with a part of the non-overlapping portion 31Y. That is, the configuration of “the heat transfer member 85 is continuously disposed from the region overlapping the non-overlapping portion 31Y to the portion in contact with at least one of the plurality of bumps 70” includes a configuration in which the heat transfer member 85 overlaps with a portion of the non-overlapping portion 31Y and a configuration in which the heat transfer member 85 overlaps with a portion of one bump 70 or is in contact with the one bump 70 in plan view.

The transistor 31 (FIG. 2) disposed in the semiconductor device 10 mounted on the semiconductor module according to the first embodiment is a MOS-FET, but the transistor 31 may be a bipolar transistor. In a case where the transistor 31 is a bipolar transistor, the minimum enclosing rectangle including the emitter region, the base region, and the collector region in plan view may be considered as a region where the transistor 31 is disposed.

### Second Embodiment

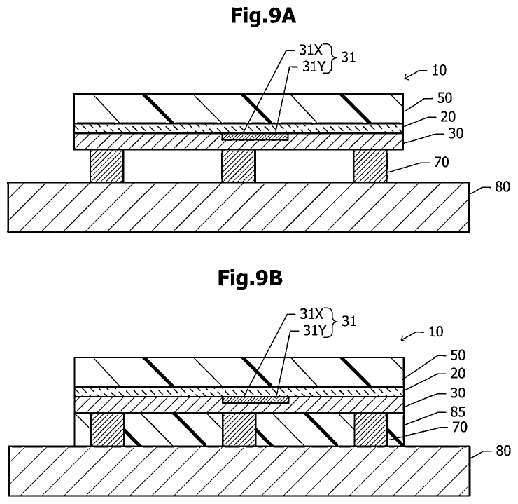

Next, the semiconductor module according to a second embodiment will be described with reference to FIGS. 8, 9A, and 9B. Configurations common to the semiconductor module according to the first embodiment described with reference to FIGS. 1 to 5A will not be described below.

FIG. 8 is a schematic cross-sectional view of a semiconductor module according to the second embodiment. In the semiconductor module (FIG. 5A) according to the first embodiment, a space is secured between the heat transfer member 85 and the mounting substrate 80, and this space is filled with the mold resin 86. On the other hand, in the semiconductor device module according to the second embodiment, the heat transfer member 85 reaches the mounting substrate 80 from the surface facing the mounting substrate 80 of the semiconductor device 10. That is, the space between the device layer 30 and the mounting substrate 80 is filled with the heat transfer member 85.

Next, a method of manufacturing the semiconductor module according to the second embodiment will be described with reference to FIGS. 9A and 9B. FIGS. 9A and 9B are cross-sectional views of the semiconductor module according to the second embodiment in the middle of manufacturing.

As shown in FIG. 9A, the semiconductor device 10 is flip-chip mounted on the mounting substrate 80. At this stage, a cavity is secured between the surface of the semiconductor device 10 facing the mounting substrate 80 and the mounting substrate 80, and the heat transfer member 85 (FIG. 8) is not disposed. As shown in FIG. 9B, the heat transfer member 85 is filled in a space between the surface of the semiconductor device 10 facing the mounting substrate 80 and the mounting substrate 80.

Hereinafter, an example of a step of filling the heat transfer member 85 will be described. A liquid resin containing a filler is injected along an end of the semiconductor device 10. The liquid resin enters the space between the surface of the semiconductor device 10 facing the mounting substrate 80 and the mounting substrate 80 together with the filler by capillary action. Thereafter, the resin is heated and cured to form the heat transfer member 85.

Next, the excellent effects of the second embodiment will be described.

Even in the second embodiment, the same excellent effects as those of the first embodiment can be obtained, that is, the temperature rise of the transistor 31 is suppressed, and the parasitic capacitance generated in the device layer 30 is not increased. In addition, in the second embodiment, the heat conducted to the heat transfer member 85 is conducted to the bump 70 and is conducted to the direct mounting substrate 80. Therefore, the heat dissipation efficiency from the transistor 31 can be further improved.

### Third Embodiment

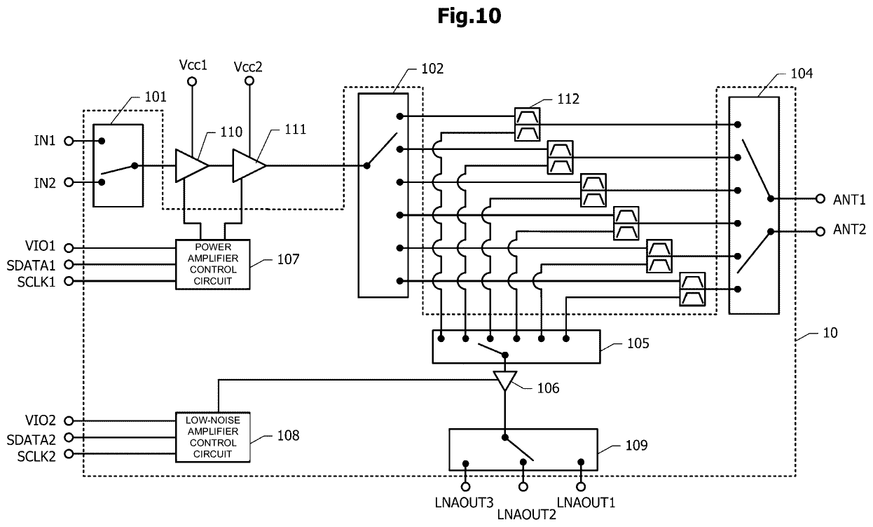

Next, a high-frequency module according to a third embodiment will be described with reference to FIG. 10. The high-frequency module according to the third embodiment includes the semiconductor module according to the first or second embodiments.

FIG. 10 is a block diagram of the high-frequency module according to the third embodiment. The high-frequency module according to the third embodiment includes the semiconductor device 10, a driver stage amplifier circuit 110, a power stage amplifier circuit 111, and a plurality of duplexers 112. The semiconductor device 10 includes an input switch 101, a band selection switch 102 for transmission, an antenna switch 104, a band selection switch 105 for reception, a low-noise amplifier 106, a power amplifier control circuit 107, a low-noise amplifier control circuit 108, and an output terminal selection switch 109 for reception. This high-frequency module has a function of performing transmission and reception in a frequency division duplex (FDD) system. In FIG. 10, the description of the impedance matching circuit to be inserted as necessary is omitted.

Two input-side contacts of the input switch 101 are connected to the respective high-frequency signal input terminals IN1 and IN2. High-frequency signals are input from the two high-frequency signal input terminals IN1 and IN2. When the input switch 101 selects one contact from the two input-side contacts, a high-frequency signal input to the selected contact is input to the driver stage amplifier circuit 110.

The high-frequency signal amplified by the driver stage amplifier circuit 110 is input to the power stage amplifier circuit 111. The high-frequency signal amplified by the power stage amplifier circuit 111 is input to an input-side contact of the band selection switch 102. In a case where the band selection switch 102 selects one contact from a plurality of output-side contacts, the high-frequency signal amplified by the power stage amplifier circuit 111 is output from the selected contact.

The plurality of output-side contacts of the band selection switch 102 are connected to respective input nodes for transmission of the plurality of duplexers 112 prepared for each band. A high-frequency signal is input to the duplexer 112 connected to an output-side contact selected by the band selection switch 102. The band selection switch 102 has a function of selecting one duplexer 112 from the plurality of duplexers 112 prepared for each band.

The antenna switch 104 has a plurality of circuit-side contacts and two antenna-side contacts. The plurality of circuit-side contacts of the antenna switch 104 are connected to respective input/output shared nodes of the plurality of duplexers 112. The two antenna-side contacts are connected to respective antenna terminals ANT1 and ANT2. Antennas are connected to the respective antenna terminals ANT1 and ANT2.

The antenna switch 104 connects the two antenna-side contacts to two respective contacts selected from the plurality of circuit-side contacts. In a case where the communication is performed using one band, the antenna switch 104 connects one circuit-side contact and one antenna-side contact. The high-frequency signal amplified by the power stage amplifier circuit 111 and passed through the duplexer 112 for a corresponding band is transmitted from an antenna connected to a selected antenna-side contact.

The band selection switch 105 for reception has six input-side contacts. Each of the six input-side contacts of the band selection switch 105 is connected to an output node for reception of the duplexer 112. An output-side contact of the band selection switch 105 is connected to the low-noise amplifier 106. A reception signal that has passed through the duplexer 112 connected to an input-side contact selected by the band selection switch 105 is input to the low-noise amplifier 106.

A circuit-side contact of the output terminal selection switch 109 is connected to an output node of the low-noise amplifier 106. Three terminal-side contacts of the output terminal selection switch 109 are connected to respective reception signal output terminals LNAOUT1, LNAOUT2, and LNAOUT3. A reception signal amplified by the low-noise amplifier 106 is output from a reception signal output terminal selected by the output terminal selection switch 109.

Power supply voltages are applied from a power terminal Vcc1 and a power terminal Vcc2 to the driver stage amplifier circuit 110 and the power stage amplifier circuit 111, respectively. The power amplifier control circuit 107 is connected to a power terminal VIO1, a control signal terminal SDATA1, and a clock terminal SCLK1. The power amplifier control circuit 107 controls the driver stage amplifier circuit 110 and the power stage amplifier circuit 111 on the basis of a digital control signal given to the control signal terminal SDATA1.

The low-noise amplifier control circuit 108 is connected to a power terminal VIO2, a control signal terminal SDATA2, and a clock terminal SCLK2. The low-noise amplifier control circuit 108 controls the low-noise amplifier 106 on the basis of a digital control signal given to the control signal terminal SDATA2.

The input switch 101, the band selection switch 102 for transmission, the antenna switch 104, the band selection switch 105 for reception, and the output terminal selection switch 109 are composed of CMOS transistors formed in the device layer 30 (FIG. 2) of the semiconductor device 10. The band selection switch 102 and the antenna switch 104 for transmission through which the high-power high-frequency signal passes are main heat sources.

Next, the excellent effects of the third embodiment will be described.

A high-frequency module according to the third embodiment includes the semiconductor device 10 according to the first or second embodiments. Therefore, the heat dissipation efficiency from the transistor constituting the band selection switch 102 for transmission and the antenna switch 104, which are the main heat sources, is improved, and the temperature rise of the transistor can be suppressed. Further, the deterioration of the high-frequency characteristics of the band selection switch 102 for transmission and the antenna switch 104 due to the parasitic capacitance is suppressed.

An amount of heat generated from a transistor constituting the input switch 101, the low-noise amplifier 106, and the output terminal selection switch 109, through which high-power high-frequency signals does not pass, is smaller than an amount of heat generated from a transistor constituting the band selection switch 102 for transmission and the antenna switch 104. Therefore, the transistors constituting the input switch 101, the low-noise amplifier 106, and the output terminal selection switch 109 do not necessarily overlap with the bumps 70 or the heat transfer member 85 (FIG. 4A) in plan view, but the transistors may overlap with the bumps 70 or the heat transfer member 85.

Each of the above-described embodiments is exemplary, and it goes without saying that partial replacement or combination of configurations shown in different embodiments is possible. The same operation and effect due to the same configuration of a plurality of embodiments will not be sequentially referred to for each embodiment. Moreover, the present disclosure is not limited to the above-described embodiments. For example, it will be obvious to a person skilled in the art that various changes, improvements, combinations, and the like are possible.

What is claimed is:

1. A semiconductor module comprising:
a mounting substrate;
a semiconductor device that is flip-chip mounted on the mounting substrate;
a mold resin that seals the semiconductor device; and
an insulating heat transfer member that is on a surface of the semiconductor device facing the mounting substrate and has a higher thermal conductivity than a thermal conductivity of the mold resin, wherein
the semiconductor device includes
a device layer including a transistor,
a plurality of bumps that are on a surface of the device layer facing the mounting substrate and are connected to the mounting substrate, and
an insulating layer that is on a surface of the device layer opposite to the surface facing the mounting substrate, and
when the mounting substrate is viewed in plan view, the transistor has a non-overlapping portion not overlapping with any of the plurality of bumps, and the heat transfer member is continuous from a region overlapping with the non-overlapping portion to at least one of the plurality of bumps.

2. The semiconductor module according to claim 1, wherein
the semiconductor device further includes a support substrate that includes a resin material and is on a surface of the insulating layer facing a side opposite to a side of the device layer.

3. The semiconductor module according to claim 1, wherein
the heat transfer member is in an entire region of the device layer other than a region where the plurality of bumps are disposed when the device layer is viewed in plan view.

4. The semiconductor module according to claim 1, wherein
the heat transfer member reaches the mounting substrate from a surface of the semiconductor device facing the mounting substrate.

5. The semiconductor module according to claim 1, wherein
the mold resin and the heat transfer member include a filler, and
a filling rate of the filler of the heat transfer member is higher than a filling rate of the filler of the mold resin.

6. The semiconductor module according to claim 1, wherein
the heat transfer member is continuous from the region overlapping with the non-overlapping portion to a bump not overlapping with the transistor among the plurality of bumps.

7. The semiconductor module according to claim 2, wherein
the heat transfer member is in an entire region of the device layer other than a region where the plurality of bumps are disposed when the device layer is viewed in plan view.

8. The semiconductor module according to claim 2, wherein
the heat transfer member reaches the mounting substrate from a surface of the semiconductor device facing the mounting substrate.

9. The semiconductor module according to claim 3, wherein
the heat transfer member reaches the mounting substrate from a surface of the semiconductor device facing the mounting substrate.

10. The semiconductor module according to claim 7, wherein
the heat transfer member reaches the mounting substrate from a surface of the semiconductor device facing the mounting substrate.

11. The semiconductor module according to claim 2, wherein
the mold resin and the heat transfer member include a filler, and
a filling rate of the filler of the heat transfer member is higher than a filling rate of the filler of the mold resin.

12. The semiconductor module according to claim 3, wherein
the mold resin and the heat transfer member include a filler, and
a filling rate of the filler of the heat transfer member is higher than a filling rate of the filler of the mold resin.

13. The semiconductor module according to claim 4, wherein
the mold resin and the heat transfer member include a filler, and
a filling rate of the filler of the heat transfer member is higher than a filling rate of the filler of the mold resin.

14. The semiconductor module according to claim 7, wherein
the mold resin and the heat transfer member include a filler, and
a filling rate of the filler of the heat transfer member is higher than a filling rate of the filler of the mold resin.

15. The semiconductor module according to claim 8, wherein
the mold resin and the heat transfer member include a filler, and
a filling rate of the filler of the heat transfer member is higher than a filling rate of the filler of the mold resin.

16. The semiconductor module according to claim 9, wherein
the mold resin and the heat transfer member include a filler, and
a filling rate of the filler of the heat transfer member is higher than a filling rate of the filler of the mold resin.

17. The semiconductor module according to claim 10, wherein
the mold resin and the heat transfer member include a filler, and
a filling rate of the filler of the heat transfer member is higher than a filling rate of the filler of the mold resin.

18. The semiconductor module according to claim 2, wherein
the heat transfer member is continuous from the region overlapping with the non-overlapping portion to a bump not overlapping with the transistor among the plurality of bumps.
